(19) United States
(12) Patent Application Publication
(10) Pub. No.: US 2026/0343819 A1
(43) Pub. Date: Oct. 29, 2026

(54) HIGH-EFFICIENCY NON-UNIFORM STRUCTURE VAPOR CHAMBER

(71) Applicant: Delta Electronics, Inc., Taoyuan City (TW)

(72) Inventors: Yang-Tung Fan, Taoyuan City (TW); Yu-Hsuan Sha, Taoyuan City (TW); Shu-Hong Chu, Taoyuan City (TW); I-Wen Chan, Taoyuan City (TW); Yi-Chung Chen, Taoyuan City (TW)

(21) Appl. No.: 19/247,465

(22) Filed: Jun. 24, 2025

(30) Foreign Application Priority Data
Apr. 29, 2025 (CN) 202510554020.1

(51) Int. Cl. H05K 7/20

(52) U.S. Cl. CPC H05K 7/20336

(57) ABSTRACT

A vapor chamber includes a housing, a working fluid and a protrusion body. The housing includes a first plate body and a second plate body facing each other, and the first plate body includes a convex portion toward a direction away from the second plate body for contacting a heat source. The working fluid is accommodated in the housing. The protrusion body is disposed on one side of the second plate body facing the first plate body and located inside the housing. The protrusion body corresponds to the convex portion in a direction perpendicular to a plane where the second plate body is located and forms at least one step on the second plate body.

### CROSS-REFERENCE TO RELATED APPLICATION

This application claims priority to China Patent Application No. 202510554020.1, filed on Apr. 29, 2025. The entire contents of the above-mentioned patent application are incorporated herein by reference for all purposes.

### FIELD OF THE INVENTION

The present disclosure relates to a vapor chamber, and more particularly to a high-efficiency non-uniform structure vapor chamber with improved thermal conductivity.

### BACKGROUND OF THE INVENTION

Vapor chambers are commonly used heat conduction devices for current electronic products. The vapor chamber includes a sealed cavity filled with working fluid, and the working fluid continuously undergoes a phase change cycle of evaporation and condensation in the cavity to achieve rapid heat conduction.

As the performance of electronic product improves, the heats generated by electronic components therein during operation have also increased significantly, and it becomes difficult for the existing vapor chamber design to meet the heat conduction requirements of high heat generating electronic components. For example, the efficiency of phase change cycle of working fluid depends on the inner structure design of the vapor chamber, so that when the heats generated from the electronic component exceed the load capacity of the existing structure design, the heats cannot be effectively transferred and causes accumulation, which results that the temperature of the electronic component cannot be effectively reduced during operation, thereby affecting the performance of the electronic product.

Therefore, there is a need of providing a vapor chamber capable of improving the drawbacks described above.

### SUMMARY OF THE INVENTION

An object of the present disclosure is to provide a vapor chamber which has an efficient thermal conductivity for meeting the heat dissipation requirements of high heat generating electronic components.

Another object of the present disclosure is to provide a vapor chamber which employs an improved inner structure to achieve a different heat conduction cycle from the conventional ones so as to improve the efficiency of heat conduction.

In accordance with an aspect of the present disclosure, a vapor chamber is provided. The vapor chamber includes a housing, a working fluid and a protrusion body. The housing includes a first plate body and a second plate body facing each other, and the first plate body includes a convex portion toward a direction away from the second plate body for contacting a heat source. The working fluid is accommodated in the housing. The protrusion body is disposed on one side of the second plate body facing the first plate body and located inside the housing. The protrusion body corresponds to the convex portion in a direction perpendicular to a plane where the second plate body is located and forms at least one step on the second plate body.

In an embodiment, the convex portion includes a convex plane for contacting the heat source, and a projection of the protrusion body and a projection of the convex plane are at least partially overlapped on the plane where the second plate body is located.

In an embodiment, a projection area of the protrusion body is equal to a projection area of the convex plane on the plane where the second plate body is located.

In an embodiment, a projection area of the protrusion body is different from a projection area of the convex plane on the plane where the second plate body is located.

In an embodiment, a width of the protrusion body in a sectional plane perpendicular to the second plate body is equal to a width of the convex plane in the sectional plane perpendicular to the second plate body.

In an embodiment, a width of the protrusion body in a sectional plane perpendicular to the second plate body is different from a width of the convex plane in the sectional plane perpendicular to the second plate body.

In an embodiment, the protrusion body has at least one height relative to the second plate body so as to form the at least one step.

In an embodiment, a surface of the protrusion body facing the convex portion has a hydrophobic layer disposed thereon.

In an embodiment, the protrusion body is made of a thermal conductive material.

In an embodiment, the protrusion body and the second plate body are formed as a monolithic piece.

In an embodiment, heats generated from the heat source are transferred to the working fluid via the convex portion, and the working fluid is heated and evaporates to generate bubbles, wherein the bubbles gather at a surface of the protrusion body facing the convex portion and then leave the surface at the at least one step to reach to the second plate body.

In an embodiment, the second plate body is contacted with a heat dissipation device, and the heat dissipation device absorbs heats, which are generated by the heat source and transferred to the second plate body through the working fluid.

In an embodiment, further including a plurality of first columns and a plurality of second columns disposed between the first plate body and the second plate body, wherein the plurality of first columns are disposed between the protrusion body and the convex portion.

In an embodiment, at least one of the plurality of first columns is placed against a surface of the protrusion body facing the convex portion.

In an embodiment, at least one of the plurality of first columns is embedded in the protrusion body.

In an embodiment, at least one of the plurality of first columns penetrates the protrusion body and abuts against the first plate body.

In an embodiment, the plurality of first columns and the plurality of second columns are made of thermal conductive materials.

### BRIEF DESCRIPTION OF THE DRAWINGS

The above contents of the present disclosure will become more readily apparent to those ordinarily skilled in the art after reviewing the following detailed description and accompanying drawings, in which:

FIG. 1A is a schematic view showing a vapor chamber according to an embodiment of the present disclosure;

FIG. 1B is a schematic view showing the vapor chamber according to the embodiment of the present disclosure from another view angle;

FIG. 2A is an exploded schematic view showing the vapor chamber according to the embodiment of the present disclosure;

FIG. 2B is an exploded schematic view showing the vapor chamber according to the embodiment of the present disclosure from another view angle;

FIG. 3 is a sectional view of A-A’ plane in FIG. 1B;

FIG. 4 is a schematic view showing the flowing of a working fluid in the vapor chamber according to the embodiment of the present disclosure;

FIGS. 5A-5C are exemplary embodiments of a protrusion body in the vapor chamber of the present disclosure; and

FIGS. 6A-6B are exemplary embodiments showing the relationship between the protrusion body and a plurality of first columns in the vapor chamber of the present disclosure.

### DETAILED DESCRIPTION OF EMBODIMENTS

The present disclosure will now be described more specifically with reference to the following embodiments. It is to be noted that the following descriptions of embodiments of this disclosure are presented herein for purpose of illustration and description only. It is not intended to be exhaustive or to be limited to the precise form disclosed.

For the sake of explanation, structures or components of vapor chambers in drawings of the present disclosure may not be drawn in proportion to the real scale, but may be scaled in different proportions in accordance with the needs for description, which is not intended to restrict the implementation of the vapor chamber of the present disclosure.

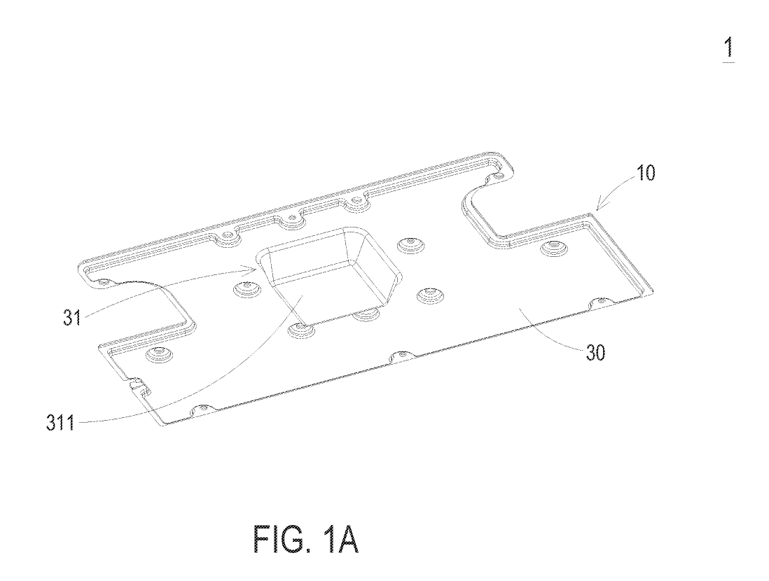

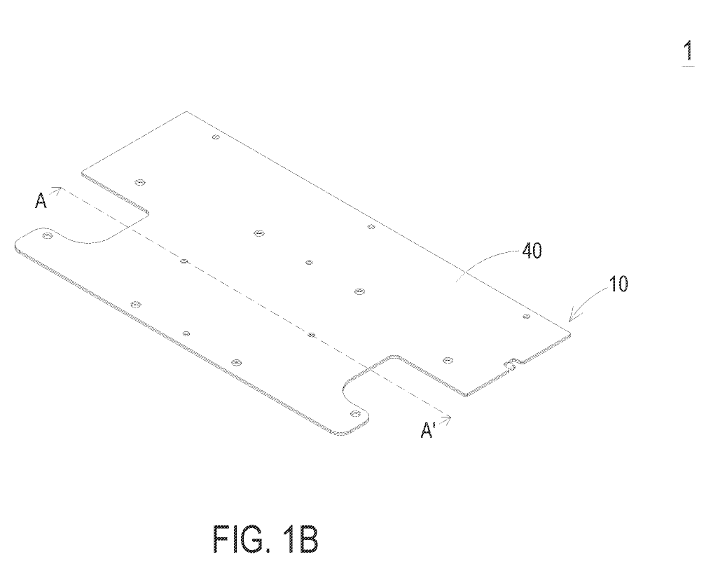

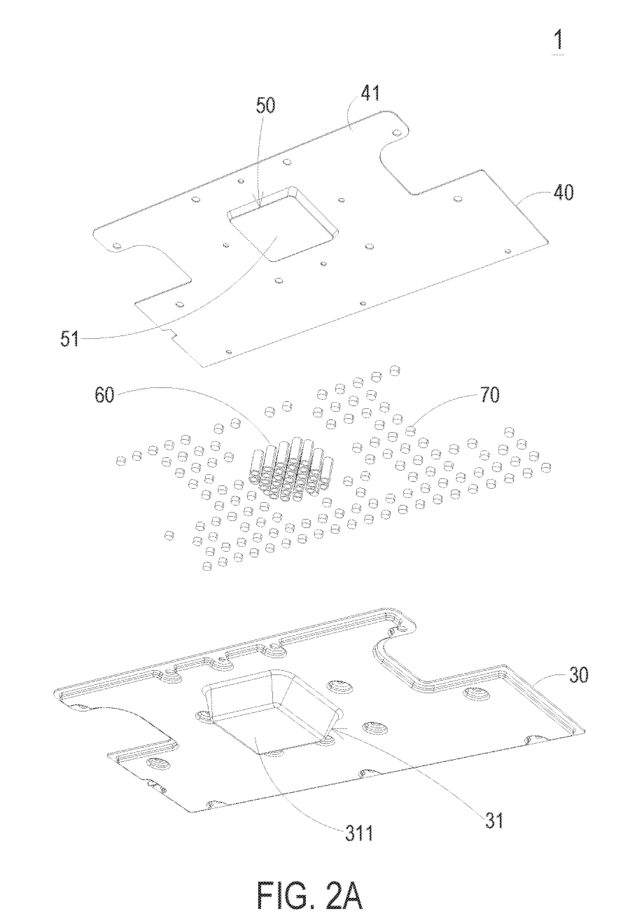

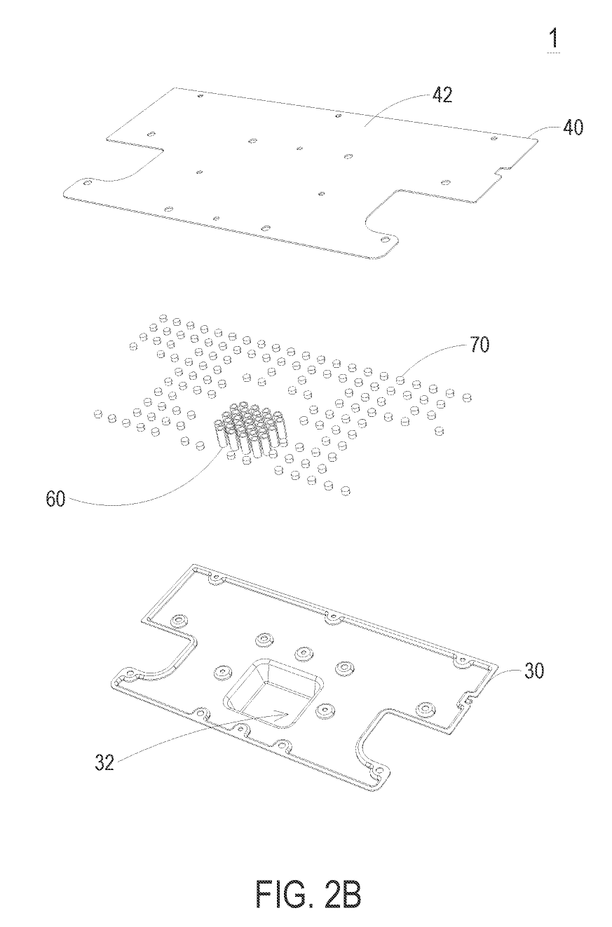

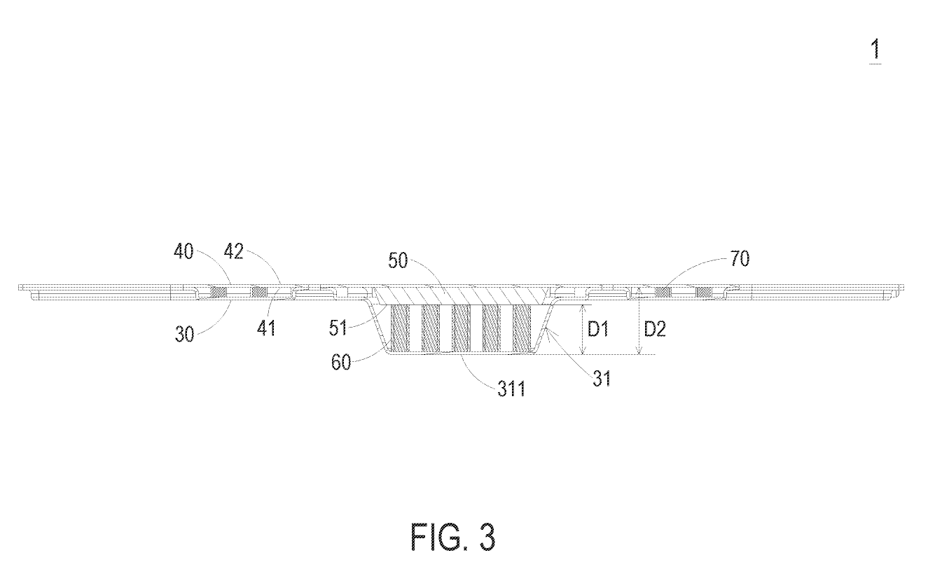

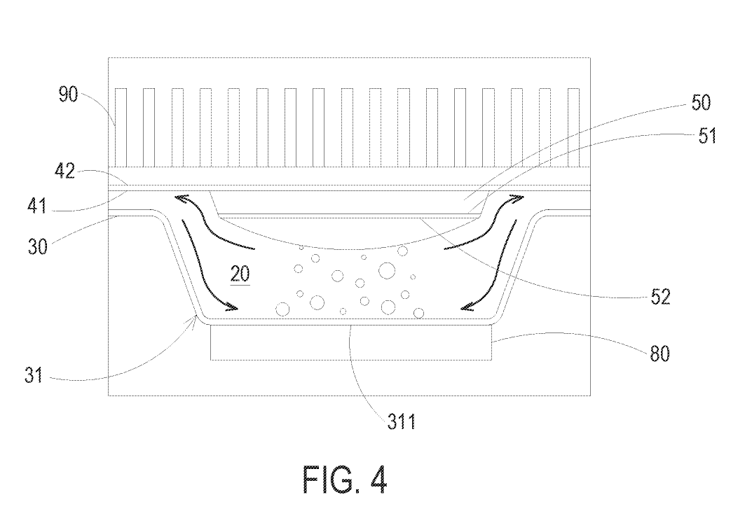

Refer to FIGS. 1A, 1B, 2A, 2B, 3, and 4. FIG. 1A is a schematic view showing a vapor chamber according to an embodiment of the present disclosure, FIG. 1B is a schematic view showing the vapor chamber according to the embodiment of the present disclosure from another view angle, FIG. 2A is an exploded schematic view showing the vapor chamber according to the embodiment of the present disclosure, FIG. 2B is an exploded schematic view showing the vapor chamber according to the embodiment of the present disclosure from another view angle, FIG. 3 is a sectional view of A-A’ plane in FIGS. 1B, and 4 is a schematic view showing the flowing of a working fluid in the vapor chamber according to the embodiment of the present disclosure. The vapor chamber 1 includes a housing 10 and a working fluid 20 accommodated in the housing 10. The housing 10 is a sealed cavity and includes a first plate body 30 and a second plate body 40 which are facing each other. The first plate body 30 includes a convex portion 31 protruded in a direction away from the second plate body 40, thereby forming a convex plane 311 at the outer surface thereof and an enlarged accommodation space 32 within the housing 10 corresponding thereto. The second plate body 40 is a plate body in a substantially planar shape and includes a first plane 41 and a second plane 42 at the opposite sides. The first plane 41 is located inside the housing 10 toward the first plate body 30, and the second plane 42 is located outside the housing 10.

The convex plane 311 of the convex portion 31 of the first plate body 30 is used to contact a heat source 80, such as a die, and through the design of the convex portion 31, the vapor chamber 1 can contact the heat source 80 in a more precise manner. The second plane 41 of the second plate body 40 is used to contact the heat dissipation device 90, such as heat dissipation fins, so as to achieve a large area heat dissipation through the plane. Under this configuration, heats absorbed from the heat source 80 via the convex portion 31 will heat the working fluid 20 around the convex portion 31 to vaporize and generate bubbles, bubbles move toward the second plate body 40, then the heat dissipation device 90 which contacts with the second plane 42 absorbs the heats so as to reduce temperature and cause condensation, and the condensed liquid flows back, thereby achieving the heat conduction cycle. However, the structure design of the convex portion 31 might easily cause the heat conduction cycle to be retained near the accommodating space 32 and unable to spread to the entire vapor chamber, thereby affecting the efficiency of heat conduction.

In order to improve the heat conduction cycle described above and thus the efficiency of heat conduction, the vapor chamber 1 of the present disclosure further includes a protrusion body 50 located inside the housing 10. The protrusion body 50 is protrudently disposed on the first plane 41 of the second plate body 40, and the position of the protrusion body 50 is corresponding to the position of the convex portion 31 in a spatially vertical direction. That is, the convex portion 31 and the protrusion body 50 are corresponding to each other in a direction perpendicular to a plane where the second plate body 40 is located, namely, the projections of the convex portion 31 and of the protrusion body 50 are at least partially overlapped on the plane where the second plate body 40 is located, for example, completely overlapped or partially staggered. Moreover, the protrusion body 50 forms a step on the first plane 41. For example, in an embodiment, the protrusion body 50 can be a cube, and forms a protruding platform on the first plane 41, resulting in a step between the platform and the plane. Therefore, a distance D1 between the convex plane 311 of the convex portion 31 and a surface 51 of the protrusion body 50 facing the first plate body 30 is less than a distance D2 between the convex plane 311 and the first plane 41, that is, the accommodation space 32 is reduced due to the arrangement of the protrusion body 50.

Under this configuration, as shown in FIG. 4, when the convex portion 31 contacts the heat source 80 and the working fluid 20 is heated to generate bubbles, since the position of the protrusion body 50 corresponds to the convex portion 31, the bubbles will first gather upward on the surface 51 of the protrusion body 50, and then, subsequent bubbles continuously generated will keep moving upwards to provide the kinetic energy to displace the bubbles above, so that the bubbles can quickly leave the surface 51 and be discharged from the edge(s) of the protrusion body 50, namely, discharged from the step. Accordingly, the heat conduction cycle caused by the bubbles can more easily be carried out of the accommodation space 32.

More specifically, in the present disclosure, on one hand, the bubbles can reach the surface 51 more quickly because the protrusion body 50 shortens the distance between the bottom of the accommodation space 32 and the first plane 41, and on the other hand, the shortened distance also increases the pressure, further causing the bubbles to more quickly leave the surface 51 and be discharged from the edge(s) of the protrusion body 50, and then rise again to the first plane 41 surrounding the protrusion body 50, thereby effectively allowing the heat conduction cycle to spread to the outer first plane 41. Therefore, compared to the manner of only relying on the rising of hot bubbles and the falling of condensed liquids, the arrangement of the protrusion body 50 in the vapor chamber 1 of the present disclosure can effectively expand and accelerate the heat conduction cycle and increase the utilization rate of the heat dissipation surface, thereby improving the efficiency of heat conduction and enhancing the operating performance of the vapor chamber 1.

In an embodiment, the surface 51 of the protrusion body 50 may be coated with a hydrophobic layer 52 so as to increase the speed at which the bubbles leave the surface 51 and are discharged from the edge(s) of the protrusion body 50.

The disposition of the protrusion body 50 on the first plane 41 can be implemented in various manners. For example, in an embodiment, the protrusion body 50 is implemented to combine to the first plane 41 of the second plate body 40, such as through soldering or mechanical engagement, and in another embodiment, the protrusion body 50 and the second plate body 40 are formed as a monolithic piece, but not limited thereto. Furthermore, the material of the protrusion body 50 is mainly a thermal conductive material, such as copper, and can be the same as or different from the material of the second plate body 40 without limitation.

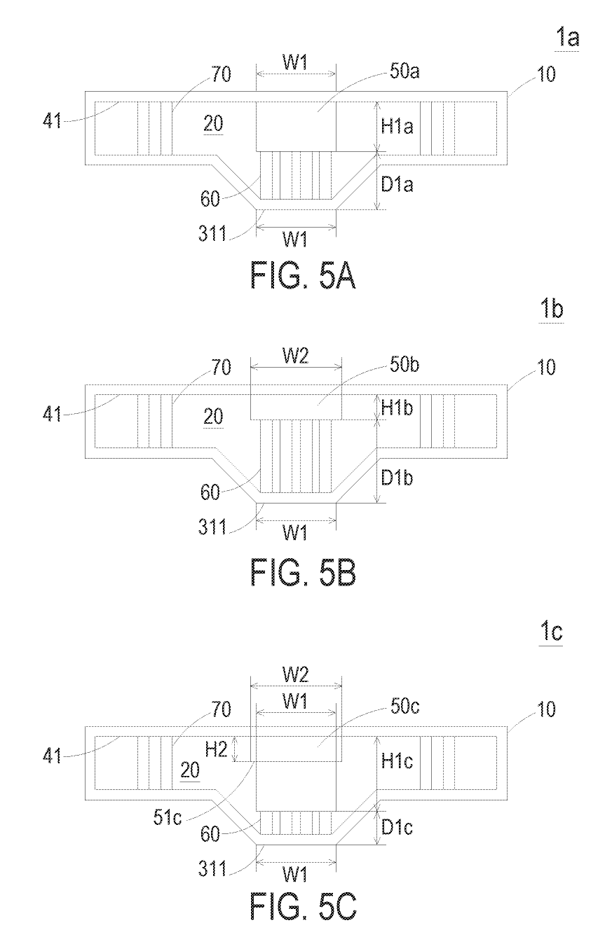

In practices, the protrusion body 50 can be implemented into various forms. First, the protruding height of the protrusion body relative to the first plane 41 can be changed in accordance with practical requirements. For example, in the embodiments shown in FIGS. 5A-5C, in the vapor chambers 1a, 1b, 1c, the protrusion bodies 50a, 50b, 50c respectively have different first heights H1a, H1b, H1c relative to the first plane 41. The difference in heights determines different distances D1a, D1b, D1c between the convex plane 311 and the protrusion bodies 50a, 50b and 50c and also the respective reduced ranges of the accommodation space 32 caused thereby.

Moreover, the width of the protrusion body in a cross section perpendicular to the first plane 41 and the projection area thereof on the plane where the second plate body 40 is located can respectively be the same as or different from the cross-sectional width and the projection area of the convex plane 311 in accordance with practical requirements. For example, taking the A-A' cross section as an example. In one embodiment, as shown in FIG. 5A, the widths of the protrusion body 50a and of the convex plane 311 in the same cross section perpendicular to the first plane 41 are both W1, and the projection area of the protrusion body 50a is implemented to be equal to the projection area of the convex plane 311, that is, the projections of the two are completely overlapped and identical. In another embodiment, as shown in FIG. 5B, the width W2 of the protrusion body 50b in the cross section perpendicular to the first plane 41 is greater than the width W1 of the convex plane 311 in the same cross section, and the projection area of the protrusion body 50b is greater than the projection area of the convex plane 311, that is, the projections of the two are overlapped but the projection areas are different. In other embodiments, it also can be implemented that the width of the protrusion body in a cross section perpendicular to the first plane 41 is smaller than the width of the convex plane 311 in the same cross section, and the projection area of the protrusion body is smaller than the projection area of the boss plane 311. Therefore, there is no limitation. Here, the differences of the cross-sectional widths and the projection areas of the protrusion bodies are related to the size of the space between the protrusion body and the convex portion for the working fluid 20 to pass through.

Furthermore, the number of steps formed by the protrusion body on the first plane 41 can be varied in accordance with practical requirements. For example, in an embodiment, as shown in FIGS. 2A, 2B, and 4, the protrusion body 50 is implemented as a trapezoidal cube, the projection shape thereof on the first plane 41 is substantially rectangular, and the cross-sectional shape thereof perpendicular to the first plane 41 is trapezoidal. In other embodiments, the protrusion body also can be implemented as other three dimensional shapes, such as a rectangular cube, a cylinder, a polygonal cylinder, or other three dimensional shapes; the projection shape thereof on the first plane 41 can be circular, polygonal, or other shapes; and the cross-sectional shape thereof perpendicular to the first plane 41 can be rectangular (as shown in FIGS. 5A-5B ), or other shapes, for example, as shown in FIG. 5C, the cross-sectional shape of the protrusion body 50c perpendicular to the first plane 41 is two stacked rectangles. Besides, the step formed by the protruding height of the protrusion body on the first plane 41 also can be implemented into various forms, for example, a step may have a right angle or an arc angle, and/or the angle of the step may be a right angle or an obtuse angle, which is not limited to the drawings.

In summary, the required implementation of the protrusion body can be determined by selecting various conditions thereof. For example, the reduced range of the accommodation space can be jointly determined through changing the protruding height and the cross-sectional width of the protrusion body and the number of step formed on the first plane 41, so as to change the circulation path of the working fluid and correspondingly obtain the suitable rising speed of bubbles and the suitable discharge speed of bubbles from the protrusion body, thereby controlling the heat conduction cycle and customizing the heat conduction rate that meets the heat generation of the electronic component. For example, the experimental results show that within a certain range, the protruding height of the protrusion body is positively correlated with the efficiency of heat conduction, so that the required efficiency of heat conduction can be obtained by adjusting the protruding height of the protrusion body. Therefore, for the protrusion body, the three-dimensional shape, the protruding height relative to the first plane 41, the projection shape on the first plane 41, the shape and the width in the cross section perpendicular to the first plane 41, and other conditions can all be varied in accordance with practical requirements. As long as the protrusion body can form a step on the first plane 41, it belongs to the scope of the present disclosure without being limited to the drawings.

The vapor chamber 1 of the present disclosure further includes a plurality of first columns 60 and a plurality of second columns 70 disposed in the housing 10. The first columns 60 are disposed between the protrusion body 50 and the convex portion 30, namely, within the accommodation space 32. The second columns 70 are disposed between the first plate body 30 and the first plane 41 of the second plate body 40. The first columns 60 and the second columns 70 can be implemented as sintered powders or supporting columns in accordance with practical requirements, and the materials thereof are mainly thermal conductive materials, such as copper, but not limited thereto. The numbers of the first columns 60 and the second columns 70 and the cross-sectional areas of the columns are also not limited, and can all be varied in accordance with practical requirements.

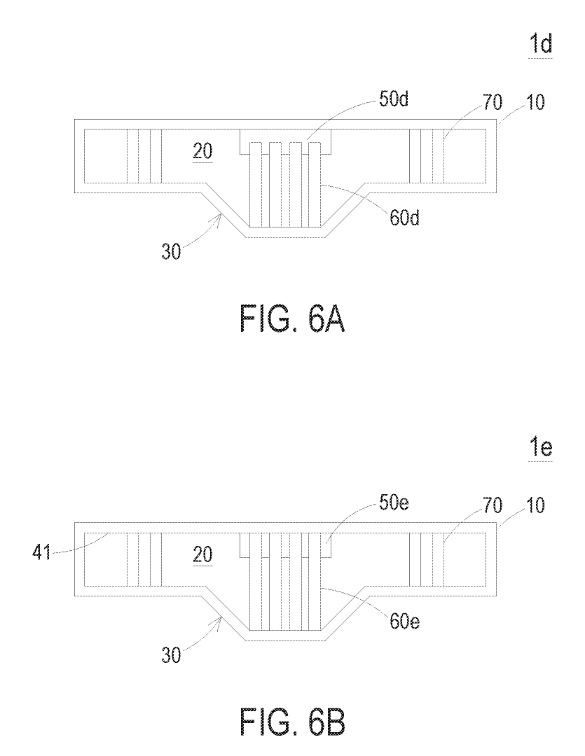

The combination between the first columns and the protrusion body can be selected to have different implementations. For example, in an embodiment, as shown in FIGS. 5A-5C, in the vapor chambers 1a, 1b, 1c, the first columns 60 are implemented to be placed between the protrusion bodies 50a, 50b, 50c and the convex portion 31, e.g., the first columns 60 and the first plate body 30 can be integrally formed as a monolithic piece, and then contact the protrusion bodies 50a, 50b, 50c, such as, by abutting against each other or soldering together; or alternatively, the first columns 60 can be implemented with two ends thereof respectively soldered to the protrusion bodies 50a, 50b, 50c and the convex portion 31. In another embodiment, as shown in FIG. 6A, in the vapor chamber 1d, the first columns 60d are implemented to embed in the protrusion body 50d. In another embodiment, as shown in FIG. 6B, in the vapor chamber 1e, the first columns 60e are implemented to penetrate the protrusion body 50e and abut against the first plane 41. Through embedding or penetration, the fixing force of the mechanical engagement can be enhanced, and in these embodiments, similarly, the first columns 60d, 60e can be implemented to be soldered on the first plate body 30 or formed with the first plate body 30 as a monolithic piece. Alternatively, the different embodiments described above can also be used in combination, for example, the first columns 60, 60d, 60e are provided at the same time. Consequently, the structural relationship between the first columns and the protrusion body can be varied in accordance with practical situations.

In conclusion, in the vapor chamber of the present disclosure, through disposing the protrusion body inside at the position corresponding to the convex portion, the circulation path of the working fluid can be changed so as to improve the circulation efficiency thereof, thereby further improving the heat conduction rate, the heat dissipation effect and the performance of the vapor chamber.

While the disclosure has been described in terms of what is presently considered to be the most practical embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A vapor chamber, comprising:
a housing comprising a first plate body and a second plate body facing each other, wherein the first plate body comprises a convex portion toward a direction away from the second plate body for contacting a heat source;
a working fluid accommodated in the housing; and
a protrusion body disposed on one side of the second plate body facing the first plate body and located inside the housing,
wherein the protrusion body corresponds to the convex portion in a direction perpendicular to a plane where the second plate body is located and forms at least one step on the second plate body.

2. The vapor chamber as claimed in claim 1, wherein the convex portion comprises a convex plane for contacting the heat source, and a projection of the protrusion body and a projection of the convex plane are at least partially overlapped on the plane where the second plate body is located.

3. The vapor chamber as claimed in claim 2, wherein a projection area of the protrusion body is equal to a projection area of the convex plane on the plane where the second plate body is located.

4. The vapor chamber as claimed in claim 2, wherein a projection area of the protrusion body is different from a projection area of the convex plane on the plane where the second plate body is located.

5. The vapor chamber as claimed in claim 2, wherein a width of the protrusion body in a sectional plane perpendicular to the second plate body is equal to a width of the convex plane in the sectional plane perpendicular to the second plate body.

6. The vapor chamber as claimed in claim 2, wherein a width of the protrusion body in a sectional plane perpendicular to the second plate body is different from a width of the convex plane in the sectional plane perpendicular to the second plate body.

7. The vapor chamber as claimed in claim 1, wherein the protrusion body has at least one height relative to the second plate body so as to form the at least one step.

8. The vapor chamber as claimed in claim 1, wherein a surface of the protrusion body facing the convex portion has a hydrophobic layer disposed thereon.

9. The vapor chamber as claimed in claim 1, wherein the protrusion body is made of a thermal conductive material.

10. The vapor chamber as claimed in claim 1, wherein the protrusion body and the second plate body are formed as a monolithic piece.

11. The vapor chamber as claimed in claim 1, wherein heats generated from the heat source are transferred to the working fluid via the convex portion, and the working fluid is heated and evaporates to generate bubbles, wherein the bubbles gather at a surface of the protrusion body facing the convex portion and then leave the surface at the at least one step to reach to the second plate body.

12. The vapor chamber as claimed in claim 1, wherein the second plate body is contacted with a heat dissipation device, and the heat dissipation device absorbs heats, which are generated by the heat source and transferred to the second plate body through the working fluid.

13. The vapor chamber as claimed in claim 1, further comprising a plurality of first columns and a plurality of second columns disposed between the first plate body and the second plate body, wherein the plurality of first columns are disposed between the protrusion body and the convex portion.

14. The vapor chamber as claimed in claim 13, wherein at least one of the plurality of first columns is placed against a surface of the protrusion body facing the convex portion.

15. The vapor chamber as claimed in claim 13, wherein at least one of the plurality of first columns is embedded in the protrusion body.

16. The vapor chamber as claimed in claim 13, wherein at least one of the plurality of first columns penetrates the protrusion body and abuts against the first plate body.

17. The vapor chamber as claimed in claim 13, wherein the plurality of first columns and the plurality of second columns are made of thermal conductive materials.
